(19) United States
(12) Patent Application Publication
(10) Pub. No.: US 2020/0366303 A1
(43) Pub. Date: Nov. 19, 2020

(54) CIRCUIT HAVING ANALOG-TO-DIGITAL CONVERSION FUNCTION AND ELECTRONIC DEVICE

(71) Applicant: JRD COMMUNICATION (SHENZHEN) LTD., SHENZHEN (CN)

(72) Inventor: YONGXIN ZENG, SHENZHEN (CN)

(21) Appl. No.: 16/762,132

(22) PCT Filed: Nov. 6, 2018
(86) PCT No.: PCT/CN2018/114187

§ 371 Date: May 6, 2020

(30) Foreign Application Priority Data
Nov. 8, 2017 (CN) 201711095743.1

(51) Int. Cl. H03M 1/00; H03K 17/687

(52) U.S. Cl. CPC H03M 1/002; H03K 17/6872

(57) ABSTRACT

The present disclosure provides a circuit having an analog-to-digital conversion function and an electronic device. The circuit includes a control circuit provided with a control port, and an analog-to-digital conversion (AD) circuit provided with an AD port. The control port is connected to the AD port, the control circuit is configured to output a first control signal and a second control signal to the AD circuit via the control port. The AD circuit is configured to be turned on according to the first control signal and is configured to be turned off according to the second control signal. Accordingly, the present disclosure may turn on and off the AD circuit as needed, thereby reducing power consumption.

### CROSS-REFERENCE TO RELATED APPLICATIONS

The present application is a 35 U.S.C. § 371 National Phase conversion of International (PCT) Patent Application No. PCT/CN2018/114187 filed on Nov. 6, 2018, which claims priority of Chinese Patent Application No. 201711095743.1, filed on Nov. 8, 2017 in the National Intellectual Property Administration of China, the contents of all of which are hereby incorporated by reference.

### TECHNICAL FIELD

The described embodiments relate to the technical field of electronic devices, specifically to the field of analog-to-digital conversion, and particularly to a circuit having an analog-to-digital conversion function and an electronic device.

### BACKGROUND

Current portable electronic products are widely used, and are all generally powered by batteries. However, for some products with small battery capacity, such as currently rather popular intelligent wearable products, lengths of time it takes to fully charge the batteries or standby time may greatly affect the user expetience. Moreover, interiors of these products generally use analog-to-digital conversion (AD) circuits.

FIG. 1 is a schematic diagram of an equivalent structure of a circuit having an analog-to-digital conversion function in the related art. As shown in FIG. 1, the circuit includes an AD circuit 10 connected to an external voltage VCC via an AD port 11. A terminal of a first voltage dividing resistor R1 is connected to a second voltage dividing resistor R2 and the AD circuit 10, and the other terminal of the first voltage dividing resistor R1 is connected to the external voltage VCC. A terminal of the second voltage dividing resistor R2 is connected to the first voltage dividing resistor R1 and the AD circuit 10, and the other terminal of the second voltage dividing resistor R2 is connected to a ground terminal GND). In the circuit design, control signals received by the AD port 11 always remain unchanged, which causes the AD circuit 10 to be always in a conducting state. It is also the same case for the AD circuit 10 even if analog-to-digital conversion is not required, thereby resulting in great power consumption.

### SUMMARY

A first aspect of the present disclosure provides a circuit having an analog-to-digital conversion function, wherein the circuit includes a control circuit provided with a control port, and an analog-to-digital conversion (AD) circuit provided with an AD port, the control port being connected to the AD port, the control circuit being configured to output a first control signal and a second control signal to the AD circuit via the control port, the AD circuit being configured to be turned on according to the first control signal and being configured to be turned off according to the second control signal, wherein the control port includes a general purpose input output (GPIO) port, and the control circuit further includes a switch unit having a control terminal connected to the control port, an input terminal connected to an external voltage VCC, and an output terminal connected to a ground terminal GND, the switch unit being configured to be turned on under control of the first control signal and being configured to be turned off under control of the second control signal.

A second aspect of the present disclosure provides a circuit having an analog-to-digital conversion function, wherein the circuit includes a control circuit provided with a control port, and an analog-to-digital conversion (AD) circuit provided with an AD port, the control port being connected to the AD port, the control circuit being configured to output a first control signal and a second control signal to the AD circuit via the control port, the AD circuit being configured to he turned on according to the first control signal and being configured to be turned off according to the second control signal.

A third aspect of the present disclosure provides an electronic device including the above control circuit having an analog-to-digital conversion function.

### BRIEF DESCRIPTION OF THE DRAWINGS

FIG. 1 is a schematic diagram of an equivalent structure of a circuit having an analog-to-digital conversion function in the related art.

FIG. 2 is a schematic structural diagram of a circuit having an analog-to-digital conversion function according to an embodiment of the present application.

FIG. 3 is a schematic diagram of an equivalent structure of the circuit shown in FIG. 2.

FIG. 4 is a schematic diagram of another equivalent structure of the circuit shown in FIG. 2.

FIG. 5 is a circuit equivalent diagram of an embodiment of a control port shown in FIG. 4,

### DETAILED DESCRIPTION

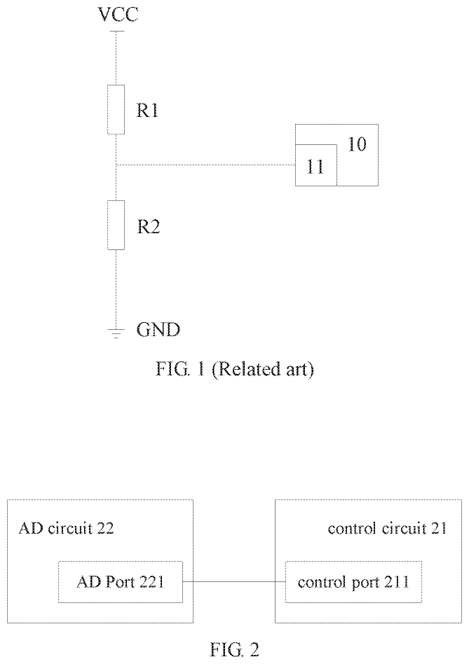

The present application provides a circuit for turning on and off the AD circuit as needed, namely, turning off the AD circuit when the electronic device does not need analog-to-digital conversion, and turning on the AD circuit when the analog-to-digital conversion is needed. FIG. 2 is a schematic structural diagram of a circuit having an analog-to-digital conversion function according to a first embodiment of the present disclosure. As shown in FIG. 2, the circuit may be integrated into an MCU (Microcontroller Unit) of an electronic device, and includes a control circuit 21 and an AD circuit 22. The control circuit 21 is provided with at least one port, for example, a control port 211 implemented with a GPIO (General Purpose Input Output) interface. The control circuit 21 is connected to the AD port 221 of the AD circuit 22 via the control port 211,

Based on the design, the control circuit 21 outputs control signals to the AD circuit 22 via the control port 211, and controls ON and OFF of the AD circuit 22 according to different control signals. Specifically, when the control circuit 21 outputs a first control signal, the AD circuit 22 is turned on, and when the control circuit 21 outputs a second control signal, the AD circuit 22 is turned off.

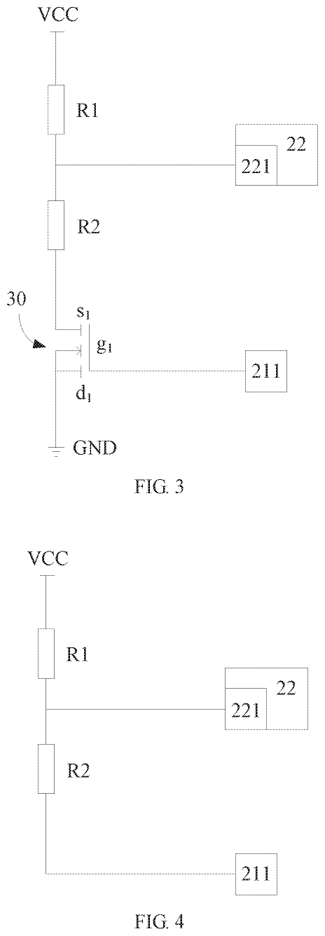

In an actual application scenario, the control circuit 21 may output the first control signal and the second control signal according to OFF and ON of a switch unit. The technical solution of the present embodiment will be clearly and completely described below in conjunction with FIGS. 3-5. It should be understood that, the embodiments described in the following disclosure are only some embodiments of the present application, rather than all of them.

Referring to FIG. 3, the control circuit 21 further includes a switch unit 30. The switch unit 30 has a control terminal g₁, an input terminal s₁, and an output terminal d₁. With the switch unit 30 being an N-type MOS (Metal-Oxide-Semiconductor) transistor as an example, the control terminal g₁, the input terminal s₁, and the output terminal d₁ of the switch unit 30 are a gate, a source, and a drain of the N-type MOS transistor, respectively. The control terminal g₁ is connected to the control port 211; the input terminal s₁ is connected to the external voltage VCC; and the output terminal d₁ is connected to the ground terminal GND.

Of course, the control circuit 21 according to the present embodiment may further be provided with resistor having voltage-dividing and current-limiting functions. As shown in FIG. 3, a terminal of the first voltage dividing resistor R1 is connected to the second voltage dividing resistor R2 and the AD circuit 22, and the other terminal of the voltage dividing resistor R1 is connected to the external voltage VCC; and a terminal of the second voltage dividing resistor R2 is connected to the first voltage dividing resistor R1 and the AD circuit 22, and the other terminal of the second voltage dividing resistor R2 is connected to the output terminal d₁ of the switch unit 30.

According to differences in electrical conduction manners, N-type MOS transistors are divided into enhanced and depleted types. For a design that the switch unit 30 is an enhanced N-type MOS transistor, the first control signal according to the present embodiment is a forward voltage. When the control terminal g₁ of the switch unit 30 receives the forward voltage output by the control port 211, the switch unit 30 is turned on. Correspondingly, the second control signal is a non-forward voltage, including a voltage of 0 and a reverse voltage. When the control terminal g₁ of the switch unit 30 receives the non-forward voltage output by the control port 211, the switch unit 30 is turned off. For a design that the switch unit 30 is a depleted N-type MOS transistor, the first control signal is a non-forward voltage. When the control terminal g₁ of the switch unit 30 receives the non-forward voltage output by the control port 211, the switch unit 30 is turned on. Correspondingly, the second control signal is a forward voltage. When the control terminal g₁ of the switch unit 30 receives the forward voltage output by the control port 211, the switch unit 30 is turned off. Of course, the switch unit 30 according to the present embodiment may also be a switch triode. The control terminal g₁, the input terminal s₁, and the output terminal d₁ of the switch unit 30 are a base, an emitter, and a collector of the switch triode, respectively. At this time, the first control signal according to the present embodiment is a high-level signal. When the control port 211 outputs a high-level signal, the switch unit 30 is turned on. Correspondingly, the second control signal is a low-level signal. When the control port 211 outputs a low-level signal, the switch unit 30 is turned off.

In conjunction with FIG. 2 and FIG. 3, when the switch unit 30 is on, since the external voltage VCC and the ground terminal GND have a voltage loop therebetween, the AD port 221 may measure a voltage and the AD circuit 22 is turned on. When the switch unit 30 is off, the AD port 221 has no voltage, and the AD circuit 22 is turned off. In view of the foregoing, the present embodiment can turn off the AD circuit 22 when the electronic device does not need to perform analog-to-digital conversion, and turn on the AD circuit 22 when it needs to perform analog-to-digital conversion, that is, turn on and off the AD circuit 22 as needed, thereby reducing power consumption and extending standby time of the electronic device.

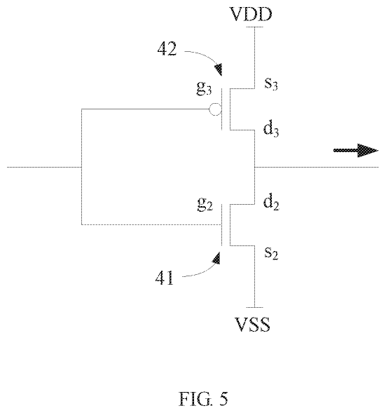

Different from configuration of the switch unit 30 outside the control port 211 shown in FIG. 3, the present application may also realize output of the first control signal and the second control signal via a switch unit integrated in the control port 211, for example, the control port 211 with a push-pull output function as shown in FIG. 4 and FIG. 5. For the same structural component, a same reference numeral is used hereinafter.

Referring to FIGS. 4 and 5, the control circuit 21 further includes a first switch unit 41 and a second switch unit 42. The first switch unit 41 has a control terminal g₂, an input terminal s₂, and an output terminal d₂. The second switch unit 42 has a control terminal g₃, an input terminal s₃, and an output terminal d₃. The control terminal g₂ of the first switch unit 41 is connected to a control signal; the input terminal s₂ is connected to a first voltage source VSS; and the output terminal d₂ is connected to the AD port 221. The control terminal g₃ of the second switch unit 42 is connected to a control signal; the input terminal s₃ is connected to a second voltage source VDD; and the output terminal d₃ is connected to the AD port 221.

Of course, the control circuit 21 may further be provided with resistors having voltage-dividing and current-limiting functions, such as a first voltage dividing resistor R1 and a second voltage dividing resistor R2 shown in FIG. 4. A terminal of the first voltage dividing resistor R1 is connected to the second voltage dividing resistor R2 and the AD port 221, and the other terminal of the first voltage dividing resistor R1 is connected to an external voltage VCC; and a terminal of the second voltage dividing resistor R2 is connected to the first voltage dividing resistor R1 and the AD port 221, and the other terminal of the second voltage dividing resistor R2 is connected to the control port 211. Specifically, the other terminal of the second voltage dividing resistor R2 is connected to the output terminal d₂ of the first switch unit 41 and the output terminal d₃ of the second switch unit 42.

In this embodiment, the first switch unit 41 and the second switch unit 42 constitute a complementary push-pull structure with a function of power amplification, The so-called complementary push-pull structure means that: one signal is used to excite the first switch unit 41 and the second switch unit 42 of different polarities to obtain two excitation signals of an equal size and opposite phases. Still with the first switch unit 41 being an enhanced N-type MOS transistor and the second switch unit 42 being a P-type MOS transistor as an example, the control terminal g₂, the input terminal s₂, and the output terminal d₂ of the first switch unit 41 are a gate, a source, and a drain of the enhanced N-type MOS transistor, respectively; and the control terminal g3, the input terminal s3, and the output terminal d3 of the second switch unit 42 are a gate, a source, and a drain of the enhanced P-type MOS transistor, respectively. The control terminal g₂ of the first switch unit 41 and the control terminal g₃ of the second switch unit 42 in parallel connection can be used as an input terminal to receive control signals output by the electronic device, and the output terminal d₂ of the first switch unit 41 and the output terminal d₃ of the second switch unit 42 are connected in parallel as an output terminal to output a first control signal or a second control signal. Therein, the control terminal g₂ of the first switch unit 41 and the control terminal g₃ of the second switch unit 42 have different polarities, and the control signals output by the electronic device are forward-biased with respect to one of them and reverse-biased with respect to the other.

When the electronic device outputs a third control signal with a high level to the input terminal, the second switch unit 42 is turned off and the first switch unit 41 is turned on. At this time, the control port 11 outputs a first control signal with a low level. The AD port 221 may measure a voltage, and the AD circuit 22 is turned on.

When the electronic device outputs a fourth control signal with a low level to the input terminal, the second switch unit 42 is turned on and the first switch unit 41 is turned off. At this time, the control port 11 outputs a second control signal with a high level. The AD port 221 has no voltage, and the AD circuit 22 is turned off.

Based on the above, the present embodiment may turn off the AD circuit 22 when the electronic device does not need to perform analog-to-digital conversion, and turn on the AD circuit 22 when it needs to perform analog-to-digital conversion, that is, turn on and off the AD circuit 22 as needed, thereby reducing power consumption and extending standby time of the electronic device.

The above description merely illustrates some exemplary embodiments of the disclosure, which however are not intended to limit the scope of the disclosure to these specific embodiments. Any equivalent structural or flow modifications or transformations made to the disclosure, or any direct or indirect applications of the disclosure on any other related fields, shall all fall in the scope of the disclosure.

1. A circuit having an analog-to-digital conversion function, wherein the circuit comprises a control circuit provided with a control port, and an analog-to-digital conversion (AD) circuit provided with an AD port, the control port being connected to the AD port, the control circuit being configured to output a first control signal and a second control signal to the AD circuit via the control port, the AD circuit being configured to be turned on according to the first control signal and being configured to be turned off according to the second control signal, wherein the control port comprises a general purpose input output (GPIO) port, and the control circuit further comprises a switch unit having a control terminal connected to the control port, an input terminal connected to an external voltage VCC, and an output terminal connected to a ground terminal GND, the switch unit being configured to be turned on under control of the first control signal and being configured to be turned off under control of the second control signal.

2. The circuit according to claim 1, wherein the switch unit comprises an enhanced N-type metal-oxide-semiconductor (MOS) transistor.

3. The circuit according to claim 1, wherein the AD circuit further comprises a first voltage dividing resistor and a second voltage dividing resistor, a terminal of the first voltage dividing resistor being connected to the second voltage dividing resistor and the AD port, the other terminal of the first voltage dividing resistor being connected to the external voltage VCC, a terminal of the second voltage dividing resistor being connected to the first voltage dividing resistor and the AD port, the other terminal of the second voltage dividing resistor being connected to the input terminal of the switch unit.

4. A circuit having an analog-to-digital conversion function, wherein the circuit comprises a control circuit provided with a control port, and an analog-to-digital conversion (AD) circuit provided with an AD port, the control port being connected to the AD port, the control circuit being configured to output a first control signal and a second control signal to the AD circuit via the control port, the AD circuit being configured to be turned on according to the first control signal and being configured to be turned off according to the second control signal.

5. The circuit according to claim 4, wherein the control circuit further comprises a switch unit having a control terminal connected to the control port, an input terminal connected to an external voltage VCC, and an output terminal connected to a ground terminal GND, the switch unit being configured to be turned on under control of the first control signal and being configured to be turned off under control of the second control signal.

6. The circuit according to claim 5, wherein the switch unit comprises an enhanced N-type metal-oxide-semiconductor (MOS) transistor.

7. The circuit according to claim 5, wherein the AD circuit further comprises a first voltage dividing resistor and a second voltage dividing resistor, a terminal of the first voltage dividing resistor being connected to the second voltage dividing resistor and the AD port, the other terminal of the first voltage dividing resistor being connected to the external voltage VCC, a terminal of the second voltage dividing resistor being connected to the first voltage dividing resistor and the AD port, the other terminal of the second voltage dividing resistor being connected to the input terminal of the switch unit.

8. The circuit according to claim 4, wherein the control circuit further comprises a first switch unit and a second switch unit, the first switch unit having a control terminal connected to a control signal, an input terminal connected to a first voltage source VSS, and an output terminal connected to the control port, the second switch unit having a control terminal connected to the control signal, an input terminal connected to a second voltage source VDD, and an output terminal connected to the control port.

9. The circuit according to claim 8, wherein the first switch unit, the second switch unit, and the control port are integrated in a same structural component.

10. The circuit according to claim 8, wherein the first switch unit is an enhanced N-type MOS transistor and the second switch unit is an enhanced P-type MOS transistor.

11. The circuit according to claim 5, wherein the AD circuit further comprises a first voltage dividing resistor and a second voltage dividing resistor, a terminal of the first voltage dividing resistor being connected to the second voltage dividing resistor and the AD port, the other terminal of the first voltage dividing resistor being connected to the external voltage VCC, a terminal of the second voltage dividing resistor being connected to the first voltage dividing resistor and the AD port, the other terminal of the second voltage dividing resistor being connected to the control port.

12. The circuit according to claim 4, wherein the control port comprises a general purpose input output (GPIO) port.

13. An electronic device, comprising a control circuit provided with a control port, and an analog-to-digital conversion (AD) circuit provided with an AD port, the control port being connected to the AD port, the control circuit being configured to output a first control signal and a second control signal to the AD circuit via the control port, the AD circuit being configured to be turned on according to the first control signal and being configured to be turned off according to the second control signal.

14. The electronic device according to claim 13, wherein the control circuit further comprises a switch unit having a control terminal connected to the control port, an input terminal connected to an external voltage VCC, and an output terminal connected to a ground terminal GND, the switch unit being configured to be turned on under control of the first control signal and being configured to be turned off under control of the second control signal.

15. The electronic device according to claim 14, wherein the switch unit comprises an enhanced N-type MOS transistor.

16. The electronic device according to claim 14, wherein the AD circuit further comprises a first voltage dividing resistor and a second voltage dividing resistor, a terminal of the first voltage dividing resistor being connected to the second voltage dividing resistor and the AD port, the other terminal of the first voltage dividing resistor being connected to the external voltage VCC, a terminal of the second voltage dividing resistor being connected to the first voltage dividing resistor and the AD port, the other terminal of the second voltage dividing resistor being connected to the input terminal of the switch unit.

17. The electronic device according to claim 13, wherein the control circuit further comprises a first switch unit and a second switch unit, the first switch unit having a control terminal connected to a control signal, an input terminal connected to a first voltage source VSS, and an output terminal connected to the control port, the second switch unit having a control terminal connected to the control signal, an input terminal connected to a second voltage source VDD, and an output terminal connected to the control port.

18. The electronic device according to claim 17, wherein the first switch unit, the second switch unit, and the control port are integrated in a same structural component.

19. The electronic device according to claim 17, wherein the first switch unit is an enhanced N-type MOS transistor and the second switch unit is an enhanced P-type MOS transistor.

20. The electronic device according to claim 14, wherein the AD circuit further comprises a first voltage dividing resistor and a second voltage dividing resistor, a terminal of the first voltage dividing resistor being connected to the second voltage dividing resistor and the AD port, the other terminal of the first voltage dividing resistor being connected to the external voltage VCC, a terminal of the second voltage dividing resistor being connected to the first voltage dividing resistor and the AD port, the other terminal of the second voltage dividing resistor being connected to the control port.
